(19) United States
(12) Patent Application Publication
(10) Pub. No.: US 2025/0087634 A1
(43) Pub. Date: Mar. 13, 2025

(54) SEMICONDUCTOR PACKAGES AND METHODS FOR MANUFACTURING THE SAME

(71) Applicant: Samsung Electronics Co., Ltd., Suwon-si (KR)

(72) Inventor: Choongbin Yim, Suwon-si (KR)

(21) Appl. No.: 18/630,149

(22) Filed: Apr. 9, 2024

(30) Foreign Application Priority Data
Sep. 8, 2023 (KR) 10-2023-0119965

(51) Int. Cl. H01L 25/065; H01L 23/00; H01L 23/31; H01L 23/48; H01L 25/00; H10B 80/00

(52) U.S. Cl. CPC H01L 25/0652; H01L 23/3107; H01L 23/481; H01L 24/08; H01L 24/16; H01L 25/50; H10B 80/00; H01L 2224/08145; H01L 2224/16145; H01L 2224/16225

(57) ABSTRACT

A semiconductor package may include a substrate, a semiconductor stacked structure on the substrate, with the semiconductor stacked structure including a logic die and a high-bandwidth memory on the logic die, one or more semiconductor dies on the substrate and arranged side by side with the semiconductor stacked structure, and one or more surface mount devices (SMD) on the semiconductor stacked structure.

### CROSS-REFERENCE TO RELATED APPLICATION

This application claims priority to and the benefit of Korean Patent Application No. 10-2023-0119965 filed in the Korean Intellectual Property Office on Sep. 8, 2023, the entire contents of which are incorporated herein by reference.

### BACKGROUND OF THE INVENTION

### (a) Field of the Invention

The present disclosure relates to semiconductor packages and to methods for manufacturing the same.

### (b) Description of the Related Art

The semiconductor industry is seeking to improve integration density so that more passive or active devices can be integrated within a given region.

Among others, the development of technology to miniaturize the circuit line width of the semiconductor front-end process has gradually faced limitations. Accordingly, the semiconductor industry is in a trend of developing semiconductor packaging technology that can have a high integration density to compensate for the limitations of semiconductor front-end processes.

Following this trend, a 2.5D package technology has been developed in which high-bandwidth memory (HBM) and logic dies are arranged side by side, with the bottom surface of the HBM and the bottom surface of the logic die connected through a silicon interposer, and a substrate placed under the silicon interposer.

However, in 2.5D package technology, as the HBM and logic die are arranged side by side, the I/O between them may be relatively wide, and this arrangement of the I/O may slow down the speed of transferring signals and power within the semiconductor package.

In addition, 2.5D package technology including high-performance circuits may require reducing power loss to implement high-performance. Since the HBM and logic die are connected with a silicon interposer, power loss may be significant due to the silicon interposer.

Additionally, the use of expensive silicon interposers increases the price of semiconductor packages.

Additionally, since a surface mount device (SMD) may be under the substrate, the number of connection members under the substrate may be reduced. As a result, the horizontal size of the 2.5D package increases.

Therefore, it is desirable to develop a new semiconductor package technology capable of solving these issues of the conventional semiconductor package technology.

### SUMMARY OF THE INVENTION

A 3.5D semiconductor package and a method for manufacturing the 3.5D semiconductor package may be provided, including a semiconductor stacked structure having a high-bandwidth memory (HBM) stacked on a logic die, a semiconductor die arranged side by side with the semiconductor stacked structure, and a surface mount device on the semiconductor stacked structure, without the use of a silicon interposer.

A semiconductor package according to some embodiments may include a substrate, a semiconductor stacked structure on the substrate, with the semiconductor stacked structure including a logic die and a high-bandwidth memory on the logic die, one or more semiconductor dies on the substrate and arranged side by side with the semiconductor stacked structure, and one or more surface mount devices (SMD) on the semiconductor stacked structure.

A semiconductor package according to some embodiments may include a substrate, a semiconductor stacked structure on the substrate, with the semiconductor stacked structure including a logic die, a high-bandwidth memory on the logic die, and a first molding material substantially surrounding the high-bandwidth memory on the logic die, the semiconductor package further including one or more semiconductor dies on the substrate and arranged side by side with the semiconductor stacked structure, one or more surface mount devices (SMD) on the semiconductor stacked structure, and a second molding material substantially surrounding the semiconductor stacked structure, the one or more semiconductor dies, and the one or more surface mount devices on the substrate.

A method for manufacturing a semiconductor package according to some embodiments may include forming a semiconductor stacked structure, with the semiconductor stacked structure including a logic die and a high-bandwidth memory on the logic die, mounting the semiconductor stacked structure on a substrate, mounting a surface mount device (SMD) on the semiconductor stacked structure, and mounting one or more semiconductor dies on the substrate and horizontally spaced apart from the semiconductor stacked structure.

By stacking HBM on a logic die without using a silicon interposer, it may be possible to reduce power loss, implement high performance, and/or reduce the price of the semiconductor package.

By providing a SMD on the semiconductor stacked structure, it may be possible to reduce the length of the electrical path between the semiconductor stacked structure and the SMD, and reduce power loss.

It may be possible to improve the performance of a semiconductor package by providing a memory die or a power management integrated circuit (PMIC) side by side with the semiconductor stacked structure.

### BRIEF DESCRIPTION OF THE DRAWINGS

FIG. 1 is a cross-sectional view illustrating a semiconductor package according to some embodiments.

FIG. 2 is a cross-sectional view illustrating a semiconductor package according to some embodiments.

FIG. 3 is a top plan view illustrating the top surface of the semiconductor package of FIGS. 1 and 2.

FIGS. 4 to 6 are cross-sectional views illustrating a method for manufacturing a semiconductor stacked structure according to some embodiments as shown in FIG. 1.

FIGS. 7 to 9 are cross-sectional views illustrating a method for manufacturing a semiconductor stacked structure according to some embodiments as shown in FIG. 2.

FIGS. 10 to 14 are cross-sectional views illustrating a method for manufacturing the semiconductor package according to some embodiments as shown in FIG. 1.

### DETAILED DESCRIPTION OF THE EMBODIMENTS

Hereinafter, the inventive concepts of present disclosure will be described in detail hereinafter with reference to the accompanying drawings, in which some examples of embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals may designate like elements throughout the specification.

Size and thickness of each constituent element in the drawings are arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a method for manufacturing the semiconductor package 100 according to some embodiments will be described with reference to the drawings.

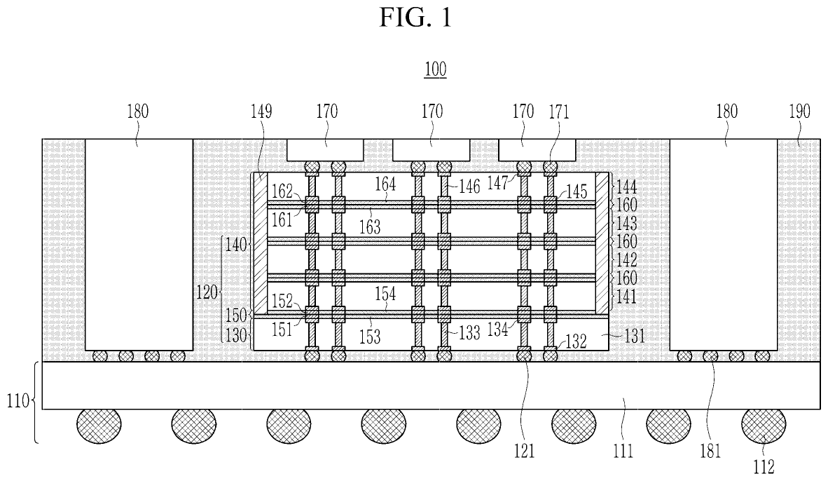

FIG. 1 is a cross-sectional view illustrating the semiconductor package 100 according to an embodiment.

Referring to FIG. 1, the semiconductor package 100 may include a substrate 110, a semiconductor stacked structure 120, a surface mount device (SMD) 170, a semiconductor die 180, and a second molding material 190. In some embodiments, the semiconductor package 100 may include a 3.5D semiconductor package. In some embodiments, the semiconductor package 100 may include a fan out wafer level package (FOWLP) or a fan out panel level package (FOPLP).

The substrate 110 may include a substrate base 111 and external connection members 112. In some embodiments, the substrate 110 may be or may include a printed circuit board. The substrate 110 may include electrical routing that mediates signals between the semiconductor stacked structure 120 and the semiconductor die 180. In some embodiments, the substrate 110 may include interconnect lines that electrically connect the semiconductor stacked structure 120 and the semiconductor die 180.

The substrate base 111 may include an insulating layer, wires, and vias. In some embodiments, the insulating layer may include at least one of a thermosetting epoxy resin and a resin containing a filler. In some embodiments, the insulating layer may include ajinomoto build-up film (ABF). In some embodiments, the wires and vias may each include at least one of copper, nickel, zinc, gold, silver, platinum, palladium, chromium, or titanium, and/or alloys thereof. The external connection member 112 may electrically connect the semiconductor package 100 to an external device (not shown). In some embodiments, the external connection member 112 may include at least one of tin, silver, lead, nickel, or copper, and/or an alloy thereof.

The semiconductor stacked structure 120 may include a logic die 130, a high-bandwidth memory 140, and a first molding material 149. The semiconductor stacked structure 120 may be a 3D package having a three-dimensional stacked structure in which the high-bandwidth memory 140 is stacked on the logic die 130. The semiconductor package 100 may be a 3.5D semiconductor package including a semiconductor stacked structure 120, which may be a 3D package, and semiconductor dies 180 which may be arranged side by side with the semiconductor stacked structure 120. The semiconductor package 100 may include the semiconductor stacked structure 120 and the semiconductor die 180 arranged in a vertical direction on the substrate 110, with the semiconductor stacked structure 120 and the semiconductor die 180 arranged horizontally in one or more horizontal directions that intersect the vertical direction. The semiconductor die 180 may be spaced apart horizontally from the semiconductor stacked structure 120.

The logic die 130 may be at the bottom in the semiconductor stacked structure 120. The logic die 130 may include a logic die base 131, first connection pads 132, first through silicon vias (TSVs) 133, and second connection pads 134. In some embodiments, the logic die 130 may include a system on chip (SoC). In some embodiments, the logic die 130 may include an application processor (AP). In some embodiments, the logic die base 131 may include at least one of a central processing unit (CPU), a graphics processing unit (GPU), system memory, a communication chip, a controller, and a sensor.

The first connection pads 132 may be between the first through silicon vias 133 and connection members 121. The first connection pad 132 may electrically connect the first through silicon via 133 to the connection member 121. In some embodiments, the first connection pads 132 may include at least one of copper, aluminum, silver, tin, gold, nickel, lead, or titanium, and/or alloys thereof.

The first through silicon vias 133 may be between the first connection pads 132 and the second connection pads 134. The first through silicon via 133 may electrically connect the second connection pad 134 to the first connection pad 132.

The first through silicon vias 133 may be formed by drilling thousands of fine holes that vertically penetrate or extend through each die and filling the holes with conductive material. In some embodiments, the holes of the first through silicon vias 133 may be formed by deep etching. In some embodiments, the holes of the first through silicon vias 133 may be formed by a laser. In some embodiments, the holes of the first through silicon vias 133 may be filled with a conductive material by electrolytic plating. In some embodiments, the first through silicon vias 133 may include at least one of tungsten, aluminum, or copper, and/or alloys thereof. Additionally, a barrier layer (not shown) may be formed between the logic die base 131 and the first through silicon via 133. In some embodiments, the barrier layer (not shown) may include at least one of titanium, tantalum, titanium nitride, or tantalum nitride, and/or alloys thereof. As such, the first through silicon vias 133 may be within the logic die base 131, and the first through silicon vias 133 are connected to the high-bandwidth memory 140 by a first interconnect structure 150. Therefore, it may be possible to increase the speed of transmitting and receiving signals and power between the logic die 130 and the high-bandwidth memory 140.

The second connection pads 134 may be between the first through silicon vias 133 and first bonding pads 151 of the first interconnect structure 150. The second connection pad 134 may electrically connect the first bonding pad 151 of the first interconnect structure 150 to the first through silicon via 133. In some embodiments, the second connection pads 134 may include at least one of copper, aluminum, silver, tin, gold, nickel, lead, or titanium, and/or alloys thereof.

The high-bandwidth memory 140 may be on (e.g., stacked on) the logic die 130. The high-bandwidth memory 140 may include a buffer die 141 and a plurality of stacked memory dies 142, 143, and 144. The high-bandwidth memory 140 may be a high-performance 3D stacked dynamic random access memory RAM (DRAM). The high-bandwidth memory 140 may be manufactured by stacking memory dies vertically to form one memory stack. The high-bandwidth memory 140 may have an advantage of having multiple memory channels through a memory stack of vertically stacked memory dies, enabling simultaneous implementation of low latency and high-bandwidth compared to conventional DRAM products, and reducing the total area occupied by individual DRAMs on a printed circuit board (PCB), which may be advantageous for high-bandwidth to area ratio, and reducing power consumption.

The buffer die 141 may be at the bottom in the high-bandwidth memory 140, and may be between the logic die 130 and the plurality of stacked memory dies 142, 143, and 144. When data is exchanged between devices with different data processing speeds, processing units and/or usage times, data loss may occur due to the differences in data processing speeds, processing units and/or usage times between each device. To prevent such loss, the buffer die 141 may be between the logic die 130 and the plurality of stacked memory dies 142, 143, and 144, and the information when exchanging data between the logic die 130 and the plurality of stacked memory dies 142, 143, and 144 may be temporarily stored in the buffer die 141. When transmitting data to the plurality of stacked memory dies 142, 143, and 144, or receiving data from the plurality of stacked memory dies 142, 143, and 144, the buffer die 141 may pass the data in order after aligning the sequence of the data.

The plurality of stacked memory dies 142, 143, and 144 may be on the buffer die 141. Each of the plurality of stacked memory dies 142, 143, and 144 may include DRAM. In some embodiments, the lowermost memory die 142 may be coupled to the buffer die 141 by hybrid bonding. In some embodiments, plurality of stacked memory dies 142, 143, and 144 may be coupled to each other by hybrid bonding. Although three stacked memory dies 142, 143, and 144 are shown in FIG. 1, the number of memory dies in the high-bandwidth memory 140 is not limited thereto, and in some embodiments the high-bandwidth memory 140 may include fewer or more memory dies.

The buffer die 141 and the plurality of stacked memory dies 142, 143, and 144 may include third connection pads 145, second through silicon vias 146, and fourth connection pads 147. In particular, the memory die 144 on the top of the high-bandwidth memory 140 generally does not include through silicon vias, but according to the present disclosure, for electrical connection with a surface mount devices 170 on the semiconductor stacked structure 120, the topmost or uppermost memory die 144 at the top of the high-bandwidth memory 140 may include the third connection pads 145, the second through silicon vias 146, and the fourth connection pads 147.

The third connection pads 145 of the buffer die 141 may be between the second through silicon vias 146 and second bonding pads 152 of the first upper connection structure 150. The third connection pad 145 of the buffer die 141 may electrically connect the second through silicon via 146 to the second bonding pad 152 of the first upper connection structure 150. The third connection pads 145 of each of the stacked memory dies 142, 143, and 144 may be between the second through silicon vias 146 and fourth bonding pads 162 of the second upper connection structure 160. The third connection pad 145 of each of the stacked memory dies 142, 143, and 144 may electrically connect the second through silicon via 146 to the fourth bonding pad 162 of the second upper connection structure 160. In some embodiments, the third connection pads 145 may include at least one of copper, aluminum, silver, tin, gold, nickel, lead, or titanium, and/or alloys thereof.

The second through silicon vias 146 may be between the third connection pads 145 and the fourth connection pads 147. The second through silicon via 146 may electrically connect the fourth connection pad 147 to the third connection pad 145.

The second through silicon vias 146 may be formed by drilling thousands of fine holes that vertically penetrate each die and filling the holes with conductive material. In some embodiments, the holes of the second through silicon vias 146 may be formed by deep etching. In some embodiments, the holes of the second through silicon vias 146 may be formed by a laser. In some embodiments, the holes of the second through silicon vias 146 may be filled with a conductive material by electrolytic plating. In some embodiments, the second through silicon vias 146 may include at least one of tungsten, aluminum, or copper, and/or alloys thereof. Additionally, a barrier layer (not shown) may be formed around the second through silicon via 146. In some embodiments, the barrier layer (not shown) may include at least one of titanium, tantalum, titanium nitride, or tantalum nitride, and/or alloys thereof.

The fourth connection pads 147 of the buffer die 141 may be between the second through silicon vias 146 and third bonding pads 161 of the second upper connection structure 160. The fourth connection pads 147 of the buffer die 141 may electrically connect the third bonding pad 161 of the second upper connection structure 160 to the second through silicon vias 146. The fourth connection pads 147 of each of the stacked memory dies 142 and 143 may be between the second through silicon vias 146 and the third bonding pads 161 of the second upper connection structure 160. The fourth connection pad 147 of each of the stacked memory dies 142 and 143 may electrically connect the third bonding pad 161 of the second upper connection structure 160 to the second through silicon via 146. The fourth connection pads 147 of the memory die 144 may be between the second through silicon vias 146 and connection members 171 of the surface mount device 170. The fourth connection pad 147 of the memory die 144 may electrically connect the connection member 171 of the surface mount device 170 to the second through silicon vias 146. In some embodiments, the fourth connection pads 147 may include at least one of copper, aluminum, silver, tin, gold, nickel, lead, or titanium, and/or alloys thereof.

The first interconnect structure 150 may be between the logic die 130 and the high-bandwidth memory 140. The logic die 130 and the high-bandwidth memory 140 may be bonded by hybrid bonding using the first interconnect structure 150. Hybrid bonding may be or may refer to a method of bonding two devices by fusing the same materials of the two devices using the bonding properties of the same materials. Here, hybrid means bonding two devices by two different types of bonding, for example, a first type of metal-to-metal bonding and a second type of non-metal-to-non-metal bonding. According to hybrid bonding, I/O with a fine pitch may be formed.

The first interconnect structure 150 may include the first bonding pads 151, the second bonding pads 152, a first silicon insulating layer 153, and a second silicon insulating layer 154. The first bonding pads 151 and the first silicon insulating layer 153 may be on the top surface of the logic die 130. The second bonding pads 152 and the second silicon insulating layer 154 may be on the bottom surface of high-bandwidth memory 140. The first bonding pad 151 may be directly bonded to the second bonding pad 152 by metal-metal hybrid bonding. The first silicon insulating layer 153 may be directly bonded to the second silicon insulating layer 154 by non-metal-non-metal hybrid bonding.

As such, according to the present disclosure, it may be possible to stack the high-bandwidth memory 140 on the logic die 130 using the first interconnect structure 150 without using a silicon interposer. Accordingly, it may be possible to implement relatively high-performance by reducing power loss that may occur due to the silicon interposer, and potentially avoid using relatively expensive silicon interposers, thereby reducing the price of the semiconductor package.

The second interconnect structure 160 may be between the buffer die 141 and the memory die 142, and between each of the stacked memory dies 142, 143, and 144 within the high-bandwidth memory 140. Within the high-bandwidth memory 140, the buffer die 141, the memory die 142, and each of the memory dies 142, 143, and 144 may be bonded by hybrid bonding using the second interconnect structure 160.

The second interconnect structure 160 may include the third bonding pads 161, the fourth bonding pads 162, a third silicon insulating layer 163, and a fourth silicon insulating layer 164. The third bonding pads 161 and the third silicon insulating layer 163 may be on the top surface of the buffer die 141 and the top surfaces of the stacked memory dies 142 and 143. The fourth bonding pads 162 and the fourth silicon insulating layer 164 may be on the bottom surfaces of the stacked memory dies 142, 143, and 144. The third bonding pad 161 may be directly bonded to the fourth bonding pad 162 by metal-metal hybrid bonding. The third silicon insulating layer 163 may be directly bonded to the fourth silicon insulating layer 164 by non-metal-non-metal hybrid bonding.

The first molding material 149 may be on the logic die 130 and mold or substantially surround the high-bandwidth memory 140. The top surface of the high-bandwidth memory 140 may not be molded by the first molding material 149. Stated differently, the top surface of the high-bandwidth memory 140 may be free from coverage by the first molding material 149.

One or more SMDs 170 may be on the semiconductor stacked structure 120. Stated differently, the substrate 110 may be on a first side of the semiconductor stacked structure 120, and the one or more SMDs 170 may be on a second side of the semiconductor stacked structure 120 that is opposite from the first side in a vertical direction. The SMD 170 may provide additional functionality or programming to the semiconductor package 100. The SMD 170 may include at least one of a resistor, an inductor, a capacitor, and a jumper. The SMD 170 may be electrically connected to the semiconductor stacked structure 120 by the connection members 171.

According to the present disclosure, the SMD 170, which was conventionally under the substrate (e.g., under the substrate 110), may be disposed on the top surface of the semiconductor stacked structure 120. In addition, the SMD 170 may be electrically connected to the second through silicon vias 146 of the memory die 144. Accordingly, it is possible to reduce the length of the electrical path between the semiconductor stacked structure 120 and the SMD 170 and power loss associated with the electrical path may be reduced.

One or more semiconductor dies 180 may be on the substrate 110. One or more semiconductor dies 180 may be arranged side by side with the semiconductor stacked structure 120. In some embodiments, one or more semiconductor dies 180 may include a power management integrated circuit (PMIC). In some embodiments, one or more semiconductor dies 180 may include multi-bank DRAM (M-DRAM).

According to the present disclosure, it may be possible to improve the performance of the semiconductor package by forming a logic die and a high-bandwidth memory, which were conventionally disposed side by side in a 2.5D package, into a 3D stacked structure, and disposing at least one of a PMIC and a M-DRAM at the position where a high-bandwidth memory was conventionally arranged.

The second molding material 190 may be on the substrate 110, and may mold or substantially surround the semiconductor stacked structure 120, one or more SMDs 170, and one or more semiconductor dies 180. In some embodiments, the top surface of the SMD 170 may be exposed to the outside from the second molding material 190. The top surface of the semiconductor die 180 may be exposed to the outside from the second molding material 190. Stated differently, the top surface of the SMD 170 and/or the top surface of the semiconductor die 180 may be free from coverage from the second molding material 190.

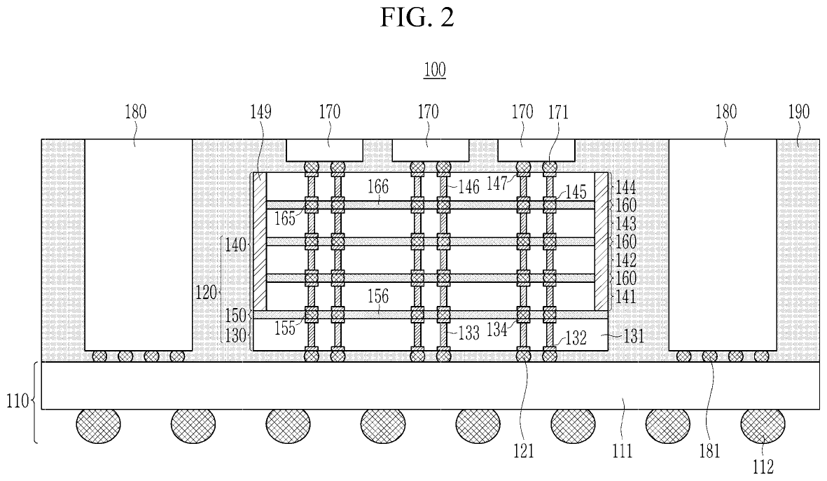

FIG. 2 is a cross-sectional view illustrating the semiconductor package 100 according to some embodiments.

In FIG. 1, the logic die 130 and the high-bandwidth memory 140 are connected by hybrid bonding by the first interconnect structure 150, and the buffer die 141 of the high-bandwidth memory 140 and each of the stacked memory dies 142, 143, and 144 are connected to each other by hybrid bonding through the second interconnect structure 160. In contrast, in FIG. 2, the logic die 130 and the high-bandwidth memory 140 may be connected by flip chip bonding by the first interconnect structure 150, and the buffer die 141 of the high-bandwidth memory 140 and each of the stacked memory dies 142, 143, and 144 may each be connected by flip chip bonding through the second interconnect structure 160.

Referring to FIG. 2, the first interconnect structure 150 may be between the logic die 130 and the high-bandwidth memory 140. The second interconnect structure 160 may be between the buffer die 141 and each of the stacked memory dies 142, 143, and 144 of the high-bandwidth memory 140.

The first interconnect structure 150 may include first connection members 155 and first insulating members 156. The first connection member 155 may be between the logic die 130 and the high-bandwidth memory 140. The first connection member 155 may electrically connect the third connection pad 145 of the buffer die 141 to the second connection pad 134 of the logic die 130. In some embodiments, the first connection member 155 may include micro bumps or solder balls. In some embodiments, the first connection member 155 may include at least one of tin, silver, lead, nickel, or copper, and/or an alloy thereof. The first insulating member 156 may be between the logic die 130 and the high-bandwidth memory 140 and surround the first connection members 155. Stress between the logic die 130 and the high-bandwidth memory 140 may be relieved by the first insulating member 156. The first insulating member 156 may include a non-conductive film (NCF).

The second interconnect structure 160 may include second connection members 165 and second insulating members 166. The second connection member 165 may be between the buffer die 141 of the high-bandwidth memory 140 and each of the stacked memory dies 142, 143, and 144 respectively, and may electrically connect them to each other.

In some embodiments, the second connection member 165 may include micro bumps or solder balls. In some embodiments, the second connection member 165 may include at least one of tin, silver, lead, nickel, or copper, and/or an alloy thereof. The second insulating member 166 may be between the buffer die 141 of the high-bandwidth memory 140 and each of the stacked memory dies 142, 143, and 144 and surround the second connection members 165. Stress between the buffer die 141 of the high-bandwidth memory 140 and each of the stacked memory dies 142, 143, and 144 may be relieved by the second insulating member 166. The second insulating member 166 may include the NCF.

In FIG. 2, all other configuration except for the first connection members 155 and the first insulating member 156 of the first interconnect structure 150, and the second connection members 165 and the second insulating member 166 of the second interconnect structure 160 are the same as the configuration described in FIG. 1. Therefore, the descriptions of the contents provided with respect to FIG. 1 may be equally applied to other configurations other than the first connection members 155 and the first insulating member 156 of the first interconnect structure 150, and the second connection members 165 and the second insulating member 166 of the second interconnect structure 160 in FIG. 2.

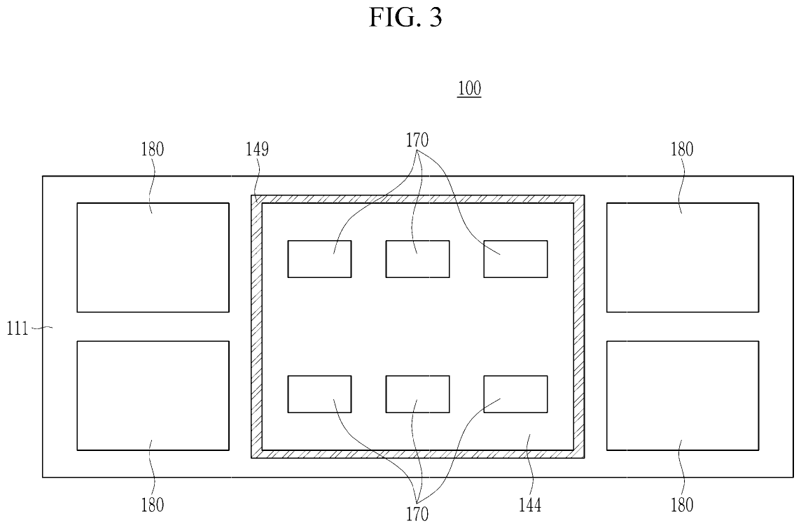

FIG. 3 is a top plan view illustrating the top surface of the semiconductor package 100 of FIGS. 1 and 2. FIG. 3 is a top plan view illustrating the semiconductor package 100 before molding the semiconductor stacked structure 120, one or more SMDs 170, and one or more semiconductor dies 180 with the second molding material 190.

Referring to FIG. 3, when the semiconductor package 100 is viewed in a top plan view, the semiconductor stacked structure 120 may be arranged at the center, and one or more semiconductor dies 180 may be provided around the semiconductor stacked structure 120. One or more SMDs 170 may be on the memory die 144 and positioned on top of the semiconductor stacked structure 120.

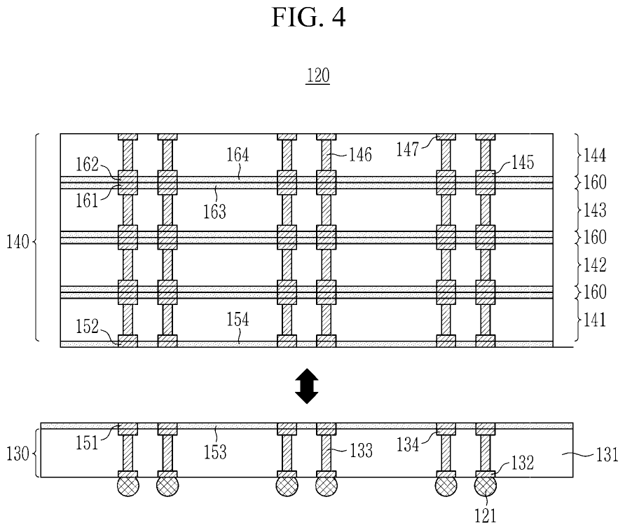

FIGS. 4 to 6 are cross-sectional views illustrating a method for manufacturing the semiconductor stacked structure 120 according to some embodiments as shown in FIG. 1.

FIG. 4 is a cross-sectional view illustrating the bonding of the logic die 130 and the high-bandwidth memory 140 by hybrid bonding.

Referring to FIG. 4, first, a heat treatment may be performed to bond the first silicon insulating layer 153 positioned on the top surface of the logic die 130 and the second silicon insulating layer 154 positioned on the bottom surface of the high-bandwidth memory 140 by hybrid bonding.

Afterwards, heat treatment may be performed to bond the first bonding pad 151 positioned on the top surface of the logic die 130 and the second bonding pad 152 positioned on the bottom surface of the high-bandwidth memory 140 by hybrid bonding.

The first bonding pad 151 may be directly bonded to the second bonding pad 152 by metal-metal hybrid bonding. Metal bonding may be made at the interface between the first bonding pad 151 and the second bonding pad 152 by metal-metal hybrid bonding.

In some embodiments, the first bonding pad 151 and the second bonding pad 152 may each include copper. In some embodiments, the first bonding pad 151 and the second bonding pad 152 may each be made of a metallic material to which hybrid bonding may be applied. The first bonding pad 151 and the second bonding pad 152 may be made of the same material, such that after hybrid bonding, the interface between the first bonding pad 151 and the second bonding pad 152 may disappear. The logic die 130 and the high-bandwidth memory 140 may be electrically connected to each other through the first bonding pad 151 and the second bonding pad 152.

The first silicon insulating layer 153 may be directly bonded to the second silicon insulating layer 154 by non-metal-non-metal hybrid bonding. Covalent bonding may be made at the interface between the first silicon insulating layer 153 and the second silicon insulating layer 154 by non-metal-non-metal hybrid bonding. In some embodiments, the first silicon insulating layer 153 and the second silicon insulating layer 154 may each include silicon oxide or TEOS forming oxide. In some embodiments, the first silicon insulating layer 153 and the second silicon insulating layer 154 may each include SiO₂. In some embodiments, the first silicon insulating layer 153 and the second silicon insulating layer 154 may each be silicon nitride, silicon oxynitride, or other suitable dielectric material. In some embodiments, the first silicon insulating layer 153 and the second silicon insulating layer 154 may each include SiN or SiCN. The first silicon insulating layer 153 and the second silicon insulating layer 154 may be made of the same material, such that after hybrid bonding, the interface between the first silicon insulating layer 153 and the second silicon insulating layer 154 may disappear.

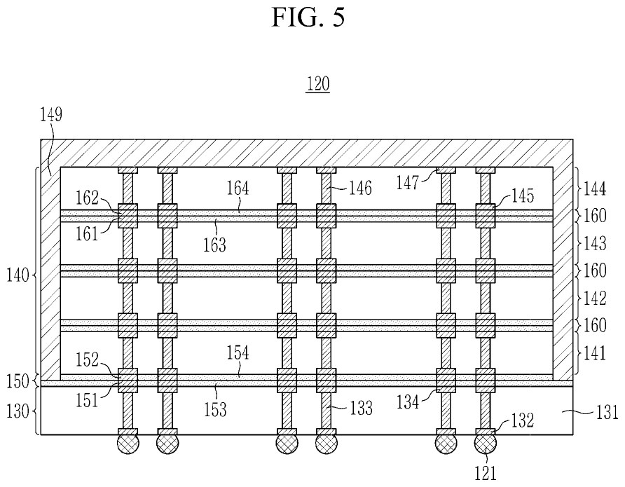

FIG. 5 is a cross-sectional view illustrating the step of molding the high-bandwidth memory 140 with the first molding material 149 on the logic die 130.

Referring to FIG. 5, on the logic die 130, the high-bandwidth memory 140 may be molded with the first molding material 149. In some embodiments, the molding process with the first molding material 149 may include compression molding or transfer molding process. In some embodiments, the first molding material 149 may include epoxy molding compound (EMC).

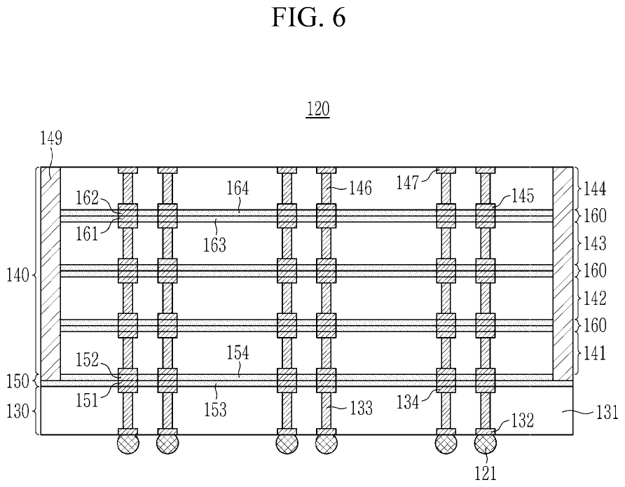

FIG. 6 is a cross-sectional view illustrating the step of planarizing the first molding material 149.

Referring to FIG. 6, chemical mechanical polishing (CMP) may be performed to level the top surface of the first molding material 149. The top of the first molding material 149 may be planarized by applying the CMP process. After performing the CMP process, the fourth connection pad 147 of the memory die 144 positioned at the top of the high-bandwidth memory 140 may be exposed from the first molding material 149.

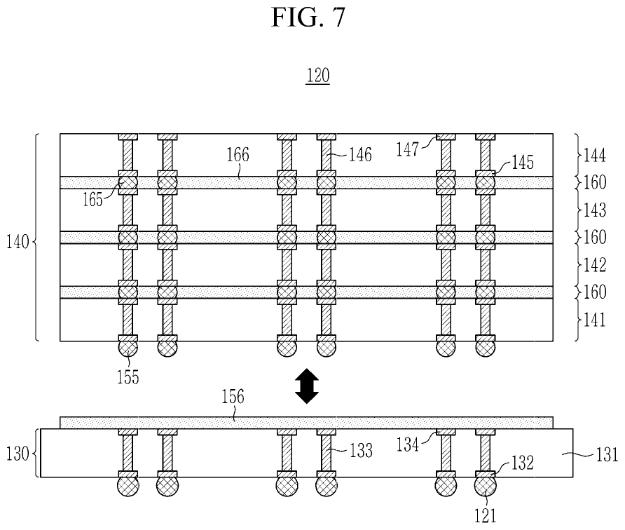

FIGS. 7 to 9 are cross-sectional views illustrating a method for manufacturing the semiconductor stacked structure 120 according to some embodiments as shown in FIG. 2.

FIG. 7 is a cross-sectional view illustrating the step of bonding the logic die 130 and the high-bandwidth memory 140 by flip chip bonding.

Referring to FIG. 7, the logic die 130 and the high-bandwidth memory 140 may be bonded by flip chip bonding.

First, a non-conductive film (NCF) may be attached as the first insulating member 156 on the logic die 130. The NCF may have adhesive properties and may be attached to the logic die 130. The NCF has an uncured state that can be deformed by external force. Next, the high-bandwidth memory 140 may be stacked on the NCF. The first connection member 155 provided in the high-bandwidth memory 140 may penetrate the NCF and contact the second connection pad 134 of the logic die 130.

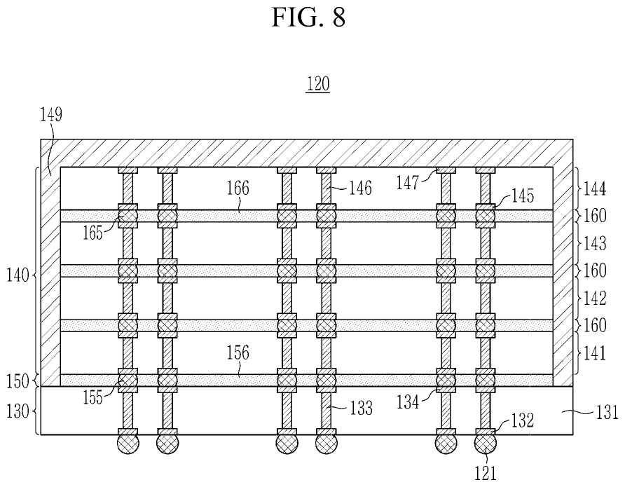

FIG. 8 is a cross-sectional view illustrating the steps of molding the high-bandwidth memory 140 with the first molding material 149 on the logic die 130.

Referring to FIG. 8, on the logic die 130, the high-bandwidth memory 140 may be molded with the first molding material 149. In some embodiments, the molding process with the first molding material 149 may include compression molding or transfer molding process. In some embodiments, the first molding material 149 may include EMC.

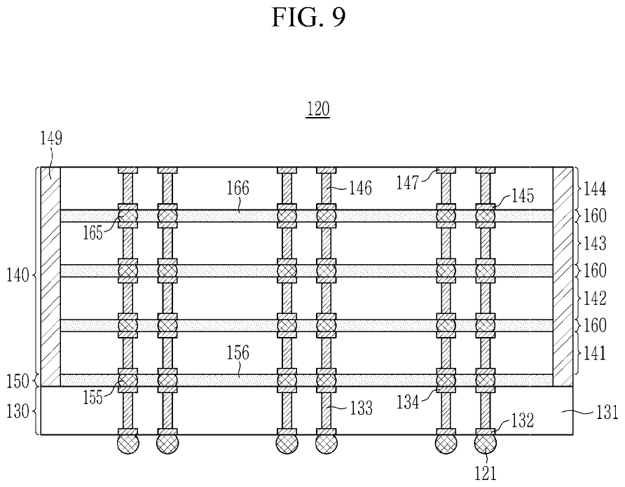

FIG. 9 is a cross-sectional view illustrating the step of planarizing the first molding material 149.

Referring to FIG. 9, CMP may be performed to level the top surface of the first molding material 149. The top surface of the first molding material 149 may be planarized by applying the CMP process. After performing the CMP process, the fourth connection pad 147 of the memory die 144 positioned at the top of the high-bandwidth memory 140 may be exposed from the first molding material 149.

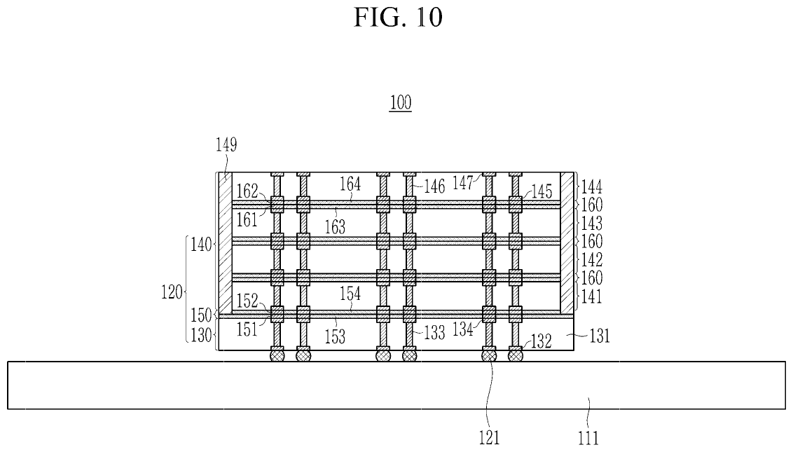

FIGS. 10 to 14 are cross-sectional views illustrating a method for manufacturing the semiconductor package 100 according to some embodiments as shown in FIG. 1.

FIG. 10 is a cross-sectional view illustrating the step of mounting the semiconductor stacked structure 120 on the substrate base 111.

Referring to FIG. 10, the semiconductor stacked structure 120 may be mounted on the substrate base 111 by flip chip bonding.

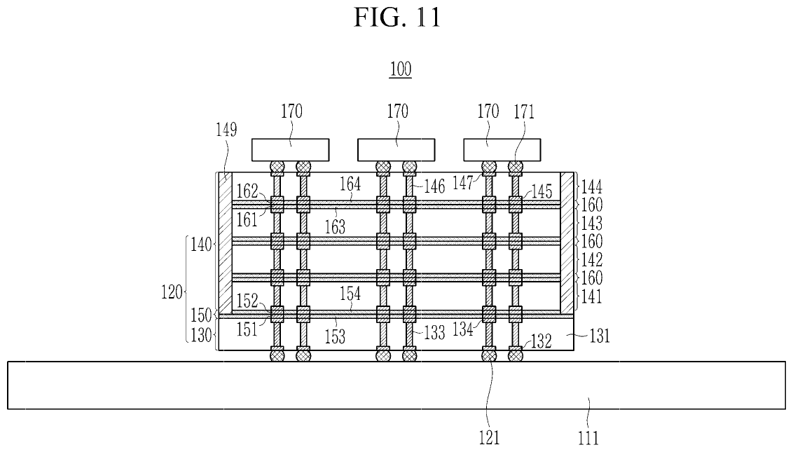

FIG. 11 is a cross-sectional view illustrating the step of mounting one or more surface mount devices 170 on the semiconductor stacked structure 120.

Referring to FIG. 11, one or more surface mount devices 170 may be mounted on the semiconductor stacked structure 120 by flip chip bonding.

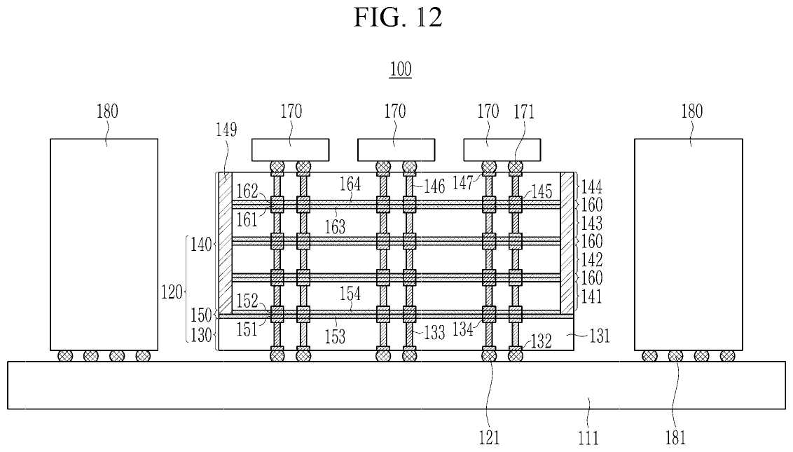

FIG. 12 is a cross-sectional view illustrating the step of mounting one or more semiconductor dies 180 on the substrate base 111.

Referring to FIG. 12, one or more semiconductor dies 180 may be mounted on the substrate base 111 by flip chip bonding.

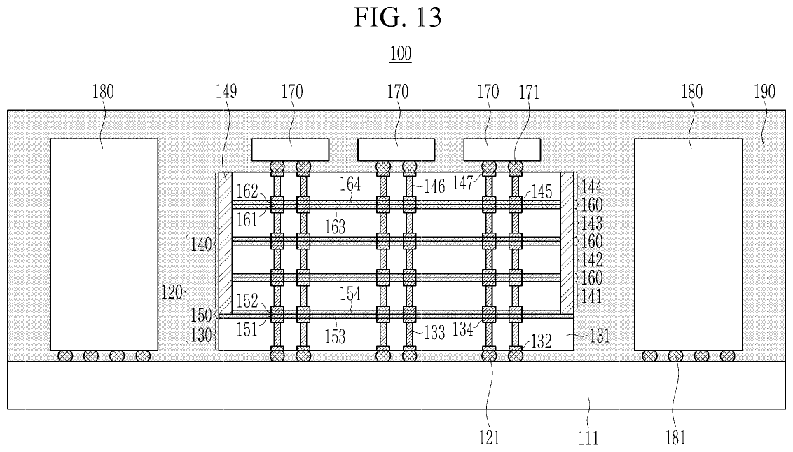

FIG. 13 is a cross-sectional view illustrating the steps of molding the high-bandwidth memory 140 with the second molding material 190 on the substrate base 111.

Referring to FIG. 13, the semiconductor stacked structure 120 may be molded on the logic die 130 using the second molding material 190. In some embodiments, the molding process with the second molding material 190 may include compression molding or transfer molding process. In some embodiments, the second molding material 190 may include EMC.

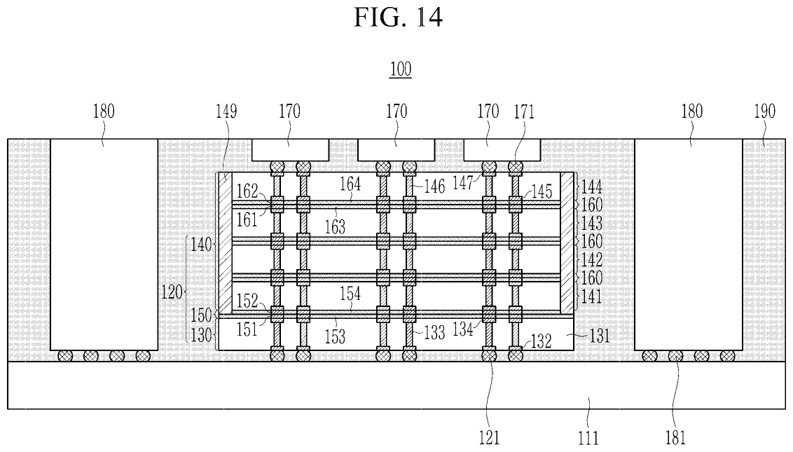

FIG. 14 is a cross-sectional view illustrating the step of planarizing the second molding material 190.

Referring to FIG. 14, CMP may be performed to level the top surface of the second molding material 190. The top surface of the second molding material 190 may be planarized by applying the CMP process. After performing the CMP process, the top surface of the one or more surface mount devices 170 and the top surface of the one or more semiconductor dies 180 may be exposed to the outside from the second molding material 190.

Afterwards, as shown in FIG. 1, the external connection members 112 may be formed on the bottom surface of the substrate 110. In some embodiments, the external connection member 112 may include at least one of tin, silver, lead, nickel, or copper, and/or an alloy thereof.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A semiconductor package, comprising:
a substrate;
a semiconductor stacked structure on the substrate, wherein the semiconductor stacked structure includes a logic die and a high-bandwidth memory on the logic die;
one or more semiconductor dies on the substrate and arranged side by side with the semiconductor stacked structure; and
one or more surface mount devices (SMD) on the semiconductor stacked structure.

2. The semiconductor package of claim 1, wherein:
the logic die comprises a plurality of first through silicon vias.

3. The semiconductor package of claim 1, wherein:
the logic die comprises a system on chip (SoC).

4. The semiconductor package of claim 1, wherein:
the logic die comprises a central processing unit (CPU) or a graphic processing unit (GPU).

5. The semiconductor package of claim 1, wherein:
the high-bandwidth memory comprises a buffer die and a plurality of memory dies stacked on the buffer die.

6. The semiconductor package of claim 5, wherein:
an uppermost memory die of the plurality of memory dies stacked on the buffer die comprises a plurality of second through silicon vias.

7. The semiconductor package of claim 6, wherein:
the one or more surface mount devices are electrically connected to the plurality of second through silicon vias.

8. The semiconductor package of claim 1, wherein:
the one or more semiconductor dies comprise a power management integrated circuit (PMIC).

9. The semiconductor package of claim 1, wherein:
the one or more semiconductor dies comprise a multi-bank DRAM (M-DRAM).

10. The semiconductor package of claim 1, wherein:
the one or more surface mount devices comprise a capacitor.

11. A semiconductor package, comprising:
a substrate;
a semiconductor stacked structure on the substrate, the semiconductor stacked structure including:
a logic die;
a high-bandwidth memory on the logic die; and
a first molding material substantially surrounding the high-bandwidth memory on the logic die;
one or more semiconductor dies on the substrate and arranged side by side with the semiconductor stacked structure;
one or more surface mount devices (SMD) on the semiconductor stacked structure; and
a second molding material substantially surrounding the semiconductor stacked structure, the one or more semiconductor dies, and the one or more surface mount devices on the substrate.

12. The semiconductor package of claim 11, wherein:
the semiconductor stacked structure further comprises an interconnect structure between the logic die and the high-bandwidth memory.

13. The semiconductor package of claim 12, wherein:
the interconnect structure comprises a plurality of micro bumps.

14. The semiconductor package of claim 12, wherein:
the interconnect structure comprises a plurality of first bonding pads and a first silicon insulating layer on a top surface of the logic die; and
the interconnection structure comprises a plurality of second bonding pads and a second silicon insulating layer on a bottom surface of the high-bandwidth memory.

15. The semiconductor package of claim 14, wherein:
each first bonding pad of the plurality of first bonding pads is directly bonded to each second bonding pad of the plurality of second bonding pads.

16. The semiconductor package of claim 14, wherein:
the first silicon insulating layer is directly bonded to the second silicon insulating layer.

17. The semiconductor package of claim 11, wherein:
a top surface of the one or more surface mount devices (SMD) is free from coverage from the second molding material.

18. The semiconductor package of claim 11, wherein:
a top surface of the one or more semiconductor dies is free from coverage from the second molding material.

19. A method for manufacturing a semiconductor package, comprising:
forming a semiconductor stacked structure, wherein the semiconductor stacked structure includes a logic die and a high-bandwidth memory on the logic die;
mounting the semiconductor stacked structure on a substrate;
mounting a surface mount device (SMD) on the semiconductor stacked structure; and
mounting one or more semiconductor dies on the substrate horizontally spaced apart from the semiconductor stacked structure.

20. The method for manufacturing the semiconductor package of claim 19, wherein:
in the forming of the semiconductor stacked structure, the logic die and the high-bandwidth memory are bonded by a hybrid bonding process.
